(19) United States
(12) Patent Application Publication
(10) Pub. No.: US 2019/0181114 A1
(43) Pub. Date: Jun. 13, 2019

(54) METHOD FOR BONDING BY DIRECT ADHESION A FIRST SUBSTRATE TO A SECOND SUBSTRATE

(71) Applicant: Commissariat a l'energie atomique et aux energies alternatives, Paris (FR)

(72) Inventors: Frank FOURNEL, Villard-Bonnot (FR); Vincent Larrey, La Murette (FR); Sofia-Antonia Lobo Kemp, Echirolles (FR); Gaelle Mauguen, Grenoble (FR)

(73) Assignee: Commissariat a l'energie atomique et aux energies alternatives, Paris (FR)

(21) Appl. No.: 16/213,458

(22) Filed: Dec. 7, 2018

(30) Foreign Application Priority Data
Dec. 8, 2017 (FR) 17 61827

(51) Int. Cl. H01L 23/00; B32B 7/04; B32B 9/04

(52) U.S. Cl. CPC H01L 24/83; B32B 7/04; B32B 2457/14; H01L 2224/83894; H01L 2224/83986; B32B 9/04

(57) ABSTRACT

A process for attaching a first substrate to a second substrate by direct bonding, the first and second substrates comprising first and second surfaces, respectively, possessing an initial bonding energy. The process includes the successive steps of: providing the first and second substrates, attaching the first substrate to the second substrate by direct bonding with the first and second surfaces, at least partially debonding the first and second substrates so as to generate electrostatic charges on portions of the first and second surfaces, and rebonding the first substrate to the second substrate by direct bonding with said portions of the first and second surfaces.

### TECHNICAL FIELD

The invention relates to the technical field of attaching two substrates to one another by direct bonding.

A particular application of the invention is in the transfer of thin layers for fabricating electronic devices.

### STATE OF THE PRIOR ART

Considering a process for attaching a first substrate to a second substrate by direct bonding, the first and second substrates comprising first and second surfaces, respectively, possessing an initial bonding energy, it is known from the prior art, in particular from the document by F. Rieutord et. al., “Dynamics of a Bonding Front”, Phys. Rev. Lett., 94, 236101, 2005 (D1 hereinafter), that there is a relationship between the initial bonding energy and the wave velocity of bonding between the first and second surfaces.

Those skilled in the art seek a direct bonding process allowing the highest possible bonding wave velocity to be obtained, in particular in order to limit the presence of peripheral zones of the first and second surfaces that cannot be bonded, or else in order to compensate for warping of the first and second surfaces.

### DISCLOSURE OF THE INVENTION

To this end, the subject of the invention is a process for attaching a first substrate to a second substrate by direct bonding, the first and second substrates comprising first and second surfaces, respectively, possessing an initial bonding energy,

the process being noteworthy in that it includes at least one step consisting in generating electrostatic charges on the first and second surfaces so as to obtain a bonding energy that is strictly higher than the initial bonding energy.

Thus, such a process according to the invention allows the wave velocity of bonding between the first and second surfaces to be increased by virtue of said at least one step of generating electrostatic charges, which allows the initial bonding energy of the first and second surfaces to be increased. Specifically, as mentioned in D1, an increase in the bonding energy of the first and second surfaces leads to an increase in the wave velocity of bonding between the first and second surfaces, as long as the external conditions remain unchanged (e.g. nature of the gas, pressure of the gas).

### Definitions

The term “substrate” is understood to mean a self-supporting physical carrier, produced in a base material allowing an electronic device or an electronic component to be fabricated. A substrate is conventionally a wafer cut from a monocrystalline ingot of semiconductor material.
The term “direct bonding” is understood to mean spontaneous bonding resulting from two surfaces being brought into direct contact, i.e. bonding in the absence of an additional element such as an adhesive, a wax or a solder. The bonding is mainly the result of van der Waals forces from the electronic interaction between the atoms or molecules of two surfaces, hydrogen bonds due to surface preparations or covalent bonds formed between the two surfaces. The terms “molecular bonding” and “direct bonding” are also used. Direct bonding is advantageously carried out at ambient temperature and pressure, and should not be conflated with thermocompression bonding, eutectic bonding or anodic bonding. Direct bonding may be followed by thermal annealing for strengthening.

The term “bonding energy” is understood to mean the energy supplied by contact between the first and second surfaces in order to propagate the direct bond. The bonding energy should be distinguished from the adhesion energy which is the energy required to separate the first and second surfaces after the bonding thereof.

The process according to the invention may include one or more of the following features.

According to one feature of the invention, said at least one step is carried out such that the generated electrostatic charges are distributed randomly over the first and second surfaces.

Thus, the inventors observed that there was no location to be favoured for the electrostatic charges. It is instead a question of applying a surface density of electrostatic charges that is sufficient to obtain a bonding energy that is strictly higher than the initial bonding energy of the first and second surfaces.

According to one feature of the invention, said at least one step is carried out such that the obtained bonding energy is between 50 mJ/m² and 150 mJ/m².

Thus, said at least one step is carried out such that the surface densities of the generated electrostatic charges allow such a bonding energy. One advantage afforded is that of obtaining a high bonding wave velocity, i.e. approximately between 10 mm/s and 40 mm/s.

According to one feature of the invention, the process includes the following steps:

a) providing the first and second substrates comprising the first and second surfaces, respectively, possessing the initial bonding energy;

b) applying electric potentials to the first and second surfaces so as to generate electrostatic charges;

c) attaching the first substrate to the second substrate by direct bonding with the first and second surfaces.

Thus, one advantage afforded by step b), i.e. applying electric potentials before bonding (i.e. floating electric potentials), is that it increases the initial bonding energy between the first and second surfaces, and hence increases the wave velocity of bonding between the first and second surfaces. Furthermore, such a step b) is straightforward to implement on an industrial scale.

According to one feature of the invention, step c) is followed by the steps of:

c₁) partially debonding the first and second substrates so as to generate electrostatic charges on portions of the first and second surfaces;
c₂) rebonding the first substrate to the second substrate by direct bonding with said portions of the first and second surfaces.

Thus, one advantage afforded by step c₁) is that it increases the bonding energy obtained upon completion of step c) between said debonded portions of the first and second surfaces, and hence increases the wave velocity of bonding between said portions of the first and second surfaces.

According to one feature of the invention, step c₁) is carried out such that the area of the debonded portions of the first and second surfaces is at least half that of the first and second surfaces, respectively.

Thus, one advantage afforded is that of being able to easily carry out step c₁) again on portions that are complementary to said debonded portions of the first and second surfaces simply by pivoting the first and second substrates.

According to one feature of the invention, steps c₁) and c₂) are reiterated on said debonded portions of the first and second surfaces.

Thus, one advantage afforded is that of increasing the bonding energy between the first and second surfaces upon each iteration, and hence of increasing the wave velocity of bonding between the first and second surfaces.

According to one feature of the invention, steps c₁) and c₂) are reiterated on at least portions that are complementary to said debonded portions of the first and second surfaces.

The term “complementary portion” is to be understood here in the mathematical sense. Specifically, if:
S denotes the total area of the first surface (or of the second surface),
S₁ denotes the area of the portion of the first surface (or of the second surface) that was debonded in step c₁),
S₂ denotes the area of the portion that is complementary to the debonded portion of the first surface (or of the second surface),
   then the term “complementary portion” signifies a zone of the first surface (or of the second surface) that was not debonded in a prior iteration of step c₁), and satisfying: S₂=S−S₁.

The term “at least one complementary portion” is understood to mean that the area of a zone that will be debonded in a reiteration of step c₁) may be larger than S₂.

Thus, one advantage afforded by reiterating steps c₁) and c₂) is that it allows the bonding energy, and hence the wave velocity of bonding between the first and second surfaces, to be progressively increased.

According to one feature of the invention, the process includes the following steps:
a′) providing the first and second substrates comprising the first and second surfaces, respectively, possessing the initial bonding energy;
b′) attaching the first substrate to the second substrate by direct bonding with the first and second surfaces;
c′) partially debonding the first and second substrates so as to generate electrostatic charges on portions of the first and second surfaces;
d′) rebonding the first substrate to the second substrate by direct bonding with said portions of the first and second surfaces.

Thus, one advantage afforded by step c′) is that it increases the initial bonding energy between the first and second surfaces, and hence increases the wave velocity of bonding between the first and second surfaces.

According to one feature of the invention, step c′) is carried out such that the area of the debonded portions of the first and second surfaces is at least half that of the first and second surfaces, respectively.

Thus, one advantage afforded is that of being able to easily carry out step c′) again on portions that are complementary to said debonded portions of the first and second surfaces simply by pivoting the first and second substrates.

According to one feature of the invention, steps c′) and d′) are reiterated on said debonded portions of the first and second surfaces.

Thus, one advantage afforded is that of increasing the bonding energy between the first and second surfaces upon each iteration, and hence of increasing the wave velocity of bonding between the first and second surfaces.

According to one feature of the invention, steps c′) and d′) are reiterated on at least some portions that are complementary to said debonded portions of the first and second surfaces.

Thus, one advantage afforded by reiterating steps c′) and d′) is that it allows the bonding energy, and hence the wave velocity of bonding between the first and second surfaces, to be progressively increased.

According to one feature of the invention, step b′) includes a step consisting in applying a voltage between the bonded first and second substrates so as to generate electrostatic charges on the first and second surfaces, the voltage preferably being between 10 V and 250 V.

Thus, one advantage afforded by applying a voltage after bonding is that it increases the initial bonding energy between the first and second surfaces, and hence increases the wave velocity of bonding between the first and second surfaces.

According to one feature of the invention, step d′) includes a step consisting in applying a voltage between the rebonded first and second substrates so as to generate electrostatic charges on the first and second surfaces, the voltage preferably being between 10 V and 250 V.

Thus, one advantage afforded by applying a voltage after bonding is that it increases the bonding energy obtained upon completion of step c′) between the first and second surfaces, and hence increases the wave velocity of bonding between the first and second surfaces.

According to one feature of the invention, the process includes the following steps:
a″) providing the first and second substrates comprising the first and second surfaces, respectively, possessing the initial bonding energy;
b″) attaching the first substrate to the second substrate by direct bonding with the first and second surfaces;
c″) applying a voltage between the bonded first and second substrates so as to generate electrostatic charges on the first and second surfaces, the voltage preferably being between 10 V and 250 V;
d″) completely debonding the first and second substrates;
e″) rebonding the first substrate to the second substrate by direct bonding with the first and second surfaces.

Thus, one advantage afforded by step c″) is that it increases the initial bonding energy between the first and second surfaces, and hence increases the wave velocity of bonding between the first and second surfaces in step e″).

According to one feature of the invention, the first and second surfaces are made of a material selected from Si, Ge, Si—Ge, SiC, SiO₂, GeO₂, SiN, Ai₂O₃, InP, AsGa, GaN.

Thus, one advantage afforded by such materials is that of allowing both direct bonding and electrostatic charges to be generated on the surface thereof.

### BRIEF DESCRIPTION OF THE DRAWINGS

Other features and advantages will become apparent in the detailed description of various embodiments of the invention, the description being accompanied by examples and references to the appended drawings.

FIG. 1 is a graph showing the bonding energy (in mJ/m²) as the abscissa and the bonding wave velocity (in mm/s) as the ordinate.

FIG. 2 is a graph showing the number of iterations of the operations of partially debonding/of rebonding the substrates as the abscissa and the bonding wave velocity (between the values V₁ and V₂) as the ordinate.

FIG. 3 is a graph showing the number of iterations of the operations of partially debonding/of rebonding the substrates as the abscissa and the bonding wave velocity (between the values V₁ and V₂) as the ordinate. The dashed portion indicates the application of a voltage on the initial bonding of the substrates.

FIG. 4 is a graph showing the number of iterations of the operations of partially debonding/of rebonding the substrates as the abscissa and the bonding wave velocity (between the values V₁ and V₂) as the ordinate. A voltage is applied each time the substrates are bonded.

FIG. 5 is a sectional schematic view (along the normal to the first and second surfaces) illustrating direct bonding of the two substrates.

FIG. 6 is a sectional schematic view (along the normal to the first and second surfaces) illustrating partial debonding of the two substrates.

FIGS. 5 and 6 are not shown to scale in order to facilitate the understanding thereof.

### DETAILED DESCRIPTION OF EMBODIMENTS

Those elements that are identical or perform the same function bear the same references for the various embodiments, for the sake of simplicity.

A subject of the invention is a process for attaching a first substrate 1 to a second substrate 2 by direct bonding, the first and second substrates 1, 2 comprising first and second surfaces 10, 20, respectively, possessing an initial bonding energy.

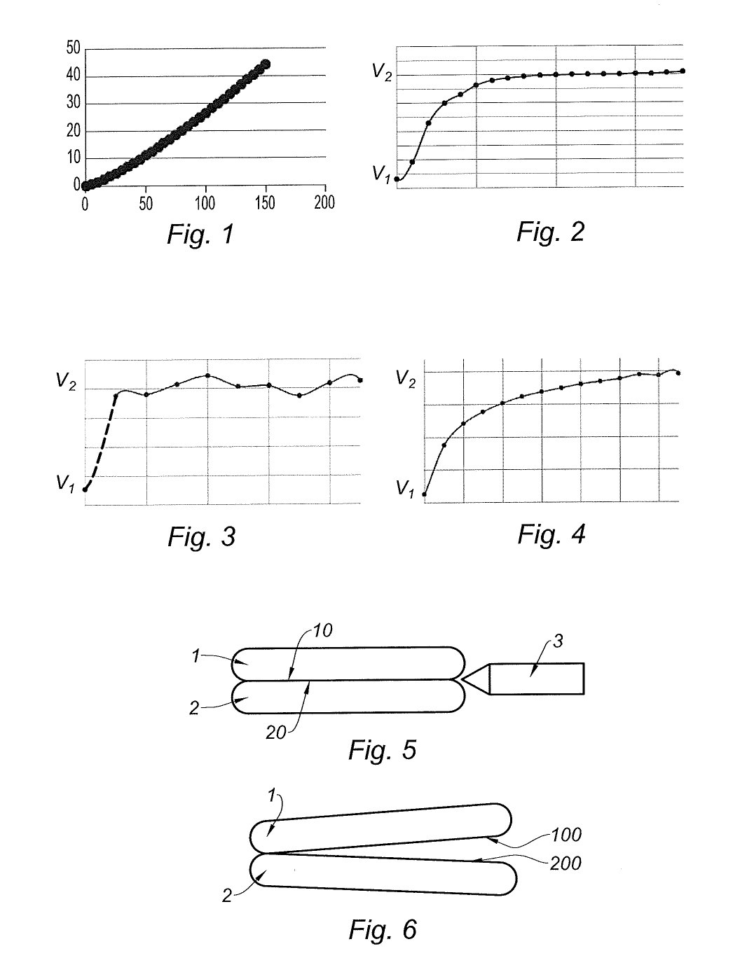

The process includes at least one step consisting in generating electrostatic charges on the first and second surfaces 10, 20 so as to obtain a bonding energy that is strictly higher than the initial bonding energy. Thus, such a process according to the invention allows the wave velocity of bonding between the first and second surfaces 10, 20 to be increased by virtue of said at least one step of generating electrostatic charges, which allows the initial bonding energy of the first and second surfaces 10, to be increased. FIG. 1 illustrates the relationship between bonding energy and bonding wave velocity.

Said at least one step is advantageously carried out such that the generated electrostatic charges are distributed randomly over the first and second surfaces 10, 20.

Said at least one step is advantageously carried out such that the obtained bonding energy is between 50 mJ/m² and 150 mJ/m².

The process can comprise the successive steps of:
providing the first and second substrates 1, 2 comprising the first and second surfaces 10, 20, respectively, possessing the initial bonding energy;
attaching the first substrate 1 to the second substrate 2 by direct bonding with the first and second surfaces 10, 20;
partially or completely (i.e. at least partially) debonding the first and second substrates 1, 2 so as to generate electrostatic charges on portions 100, 200 of the first and second surfaces 10, 20;
rebonding the first substrate 1 to the second substrate 2 by direct bonding with said portions 100, 200 of the first and second surfaces 10, 20.

The succession of bonding and debonding steps increases the bonding energy of the first and second surfaces 10, 20 upon each iteration so as to increase the wave velocity of bonding between the first and second surfaces 10, 20.

### First and Second Substrates

The first and second surfaces 10, 20 are advantageously made of a material selected from Si, Ge, Si—Ge, SiC, SiO₂, GeO₂, SiN, Al₂O₃, InP, AsGa, GaN. Such materials allow both direct bonding and electrostatic charges to be generated on the surface thereof.

When the first and second substrates 1, 2 are each produced in a material not allowing both direct bonding and electrostatic charges to be generated on the surface thereof at the same time (e.g. metal substrates 1, 2), then the first and second substrates 1, 2 each advantageously include a surface layer produced in a material allowing both direct bonding and electrostatic charges to be generated.

### First Implementation

According to the first implementation, the process includes the successive steps of:

a) providing the first and second substrates 1, 2 comprising the first and second surfaces 10, 20, respectively, possessing the initial bonding energy;

b) applying electric potentials to the first and second surfaces 10, 20 so as to generate electrostatic charges;

c) bonding the first substrate 1 to the second substrate 2 by direct bonding with the first and second surfaces 10, 20.

The electric potentials applied in step b) are floating potentials. Specifically, so as not to damage the first and second surfaces 10, 20 to be bonded, only the rear faces are brought into contact with an electrode to which the desired electric potential is applied.

Step c) is preferably carried out at ambient temperature, i.e. between 20° C. and 30° C.

Step c) may be followed by the steps of:

c₁) partially debonding the first and second substrates 1, 2 so as to generate electrostatic charges on portions 100, 200 of the first and second surfaces 10, 20;
c₂) rebonding the first substrate 1 to the second substrate 2 by direct bonding with said portions 100, 200 of the first and second surfaces 10, 20.

Step c₁) is advantageously carried out such that the area of the debonded portions 100, 200 of the first and second surfaces 10, 20 is at least half, preferably at least ⅔, that of the first and second surfaces 10, 20, respectively. Such a step c₁) allows electrostatic charges to be generated that are distributed randomly over the first and second surfaces 10, 20. As illustrated in FIG. 5, step c₁) may be carried out using a blade 3, preferably produced in a plastic material, which is inserted between the chamfered edges of the first and second substrates 1, 2.

In step c₂), the electrostatic charges that are distributed over the first and second surfaces 10, 20 are located facing one another, thereby allowing the bonding wave velocity to be increased.

Steps c₁) and c₂) are advantageously reiterated on said same debonded portions 100, 200 of the first and second surfaces 10, 20. The number of reiterations may be between 1 and 20.

Steps c₁) and c₂) are advantageously reiterated on at least portions that are complementary to said debonded portions 100, 200 of the first and second surfaces 10, 20. Steps c₁) and c₂) are advantageously reiterated on said same portions that are complementary to said debonded portions 100, 200 of the first and second surfaces 10, 20. The variation in the bonding wave velocity is illustrated in FIG. 3.

Steps c₁) and c₂) are preferably carried out at ambient temperature, i.e. between 20° C. and 30° C.

### Second Implementation

According to the second implementation, the process includes the successive steps of:

a′) providing the first and second substrates 1, 2 comprising the first and second surfaces 10, 20, respectively, possessing the initial bonding energy;

b′) attaching the first substrate 1 to the second substrate 2 by direct bonding with the first and second surfaces 10, 20;

c′) partially debonding the first and second substrates 1, 2 so as to generate electrostatic charges on portions 100, 200 of the first and second surfaces 10, 20;

d′) rebonding the first substrate 1 to the second substrate 2 by direct bonding with said portions 100, 200 of the first and second surfaces 10, 20.

Step b′) is preferably carried out at ambient temperature, i.e. between 20° C. and 30° C.

Step c′) is advantageously carried out such that the area of the debonded portions 100, 200 of the first and second surfaces 10, 20 is at least half, preferably at least ⅔, that of the first and second surfaces 10, 20, respectively. Such a step c′) allows electrostatic charges to be generated that are distributed randomly over the first and second surfaces 10, 20. As illustrated in FIG. 5, step c′) may be carried out using a blade 3, preferably produced in a plastic material, which is inserted between the chamfered edges of the first and second substrates 1, 2.

In step d′), the electrostatic charges that are distributed over the first and second surfaces 10, 20 are located facing one another, thereby allowing the bonding wave velocity to be increased.

Steps c′) and d′) are advantageously reiterated on said same debonded portions 100, 200 of the first and second surfaces 10, 20. The number of reiterations may be between 1 and 20.

Steps c′) and d′) are advantageously reiterated on at least portions that are complementary to said debonded portions 100, 200 of the first and second surfaces 10, 20. Steps c′) and c′) are advantageously reiterated on said same portions that are complementary to said debonded portions 100, 200 of the first and second surfaces 10, 20. The variation in the bonding wave velocity is illustrated in FIG. 2. Steps c′) and d′) are preferably carried out at ambient temperature, i.e. between 20° C. and 30° C.

Step b′) advantageously includes a step consisting in applying a voltage between the bonded first and second substrates 1, 2 so as to generate electrostatic charges on the first and second surfaces 10, 20, the voltage preferably being between 10 V and 250 V. Such a step b′) allows electrostatic charges that are distributed randomly over the first and second surfaces 10, 20 to be generated, the electrostatic charges being located facing one another. Step d′) advantageously includes a step consisting in applying a voltage between the first and second rebonded substrates 1, 2 so as to generate electrostatic charges on the first and second surfaces 10, 20, the voltage preferably being between 10 V and 250 V. Such a step d′) allows electrostatic charges that are distributed randomly over the first and second surfaces 10, 20 to be generated, the electrostatic charges being located facing one another. The variation in the bonding wave velocity is illustrated in FIG. 4, when voltages are applied to the bonds of steps b′) and d′).

### Third Implementation

According to the third implementation, the process includes the successive steps of:

a″) providing the first and second substrates 1, 2 comprising the first and second surfaces 10, 20, respectively, possessing the initial bonding energy;

b″) attaching the first substrate 1 to the second substrate 2 by direct bonding with the first and second surfaces 10, 20;

c″) applying a voltage between the bonded first and second substrates 1, 2 so as to generate electrostatic charges on the first and second surfaces 10, 20, the voltage preferably being between 10 V and 250 V;

d″) completely debonding the first and second substrates 1, 2;

e″) rebonding the first substrate 1 to the second substrate 2 by direct bonding with the first and second surfaces 10, 20.

Steps b″), d″) and e″) are preferably carried out at ambient temperature, i.e. between 20° C. and 30° C.

As illustrated in FIG. 5, step d″) may be carried out using a blade 3, preferably produced in a plastic material, which is inserted between the chamfered edges of the first and second substrates 1, 2.

### Implementation Example No. 1

The first and second substrates 1, 2 are two (001) silicon wafers of 200 mm in diameter and 725 μm in thickness. The first and second substrates 1, 2 are cleaned and hydrolysed in baths of ozonated deionized water and in an APM (ammonia-peroxide mixture) solution at 70° C. The first and second substrates 1, 2 are direct-bonded at ambient temperature and at ambient pressure. V₁ denotes the mean wave velocity obtained in the spontaneous propagation of the direct bond. The bonding wave is imaged by means of an infrared camera. An infrared light source (having a wavelength of about 1 μm) is placed below the bond. Next, a plastic blade 3 is inserted between the first and second substrates 1, 2, taking care only to touch the chamfers and not the surfaces of the substrates 1, 2 so as to avoid transferring particulate or organic contaminants to the bonding interface. Two thirds of the first and second surfaces 10, 20 are debonded. Next, the plastic blade 3 is removed and the bond propagates anew. This operation is reiterated about 10 times. As can be seen in FIG. 2, the bonding wave velocity progressively increases with the number of partial debonding operations. A bonding wave velocity V₂ that is about twice the speed of V₁ is obtained. In this example, V₁ has a value of about 16 mm/s and V₂ has a value of about 32 mm/s. Next, the bonded first and second substrates 1, 2 may be pivoted by 180° and the debonding operations reiterated on complementary portions in order to obtain a high bonding energy over the entire area of the first and second surfaces 10, 20.

### Implementation Example No. 2

The first and second substrates 1, 2 are two (001) silicon wafers of 200 mm in diameter and 725 μm in thickness, covered with a thermal oxide layer of 145 nm in thickness. The first and second substrates 1, 2 are cleaned and hydrolysed in baths of ozonated deionized water and in an APM (ammonia-peroxide mixture) solution at 70° C. A dinitrogen N₂ plasma is formed on the first and second substrates 1, 2 for 15 s under a pressure of 0.3 mbar of nitrogen in RIE (reactive-ion etching) mode at a frequency of 13.56 MHz. The first and second substrates 1, 2 are direct-bonded at ambient temperature and at ambient pressure. V₁ denotes the mean wave velocity obtained in the spontaneous propagation of the direct bond. Next, a voltage of 75 V is applied to the bond. Partial debonding results and a bonding wave velocity V₂ that is about twice the speed of V₁ is immediately obtained. Subsequent partial debonding operations have little effect in the case described in FIG. 2. In this example, V₁ has a value of about 30 mm/s and V₂ has a value of about 60 mm/s.

### Implementation Example No. 3

The first and second substrates 1, 2 are two (001) silicon wafers of 200 mm in diameter and 725 μm in thickness, covered with a thermal oxide layer of 145 nm in thickness. The first and second substrates 1, 2 are cleaned and hydrolysed in baths of ozonated deionized water and in an APM (ammonia-peroxide mixture) solution at 70° C. The first and second substrates 1, 2 are direct-bonded at ambient temperature and at ambient pressure. V₁ denotes the mean wave velocity obtained in the spontaneous propagation of the direct bond. Next, the first and second substrates 1, 2 are completely debonded. A voltage of 250 V is applied to one of the two substrates 1, 2. The first and second substrates 1, 2 are direct-bonded anew, and a bonding wave velocity V₂ that is about 50% higher than V₁ is measured. In this example, it is not necessary to perform the first direct bonding operation, it being provided here only to show the increase in wave propagation velocity from V₁ to V₂. In this example, V₁ has a value of about 20 mm/s and V₂ has a value of about 30 mm/s.

### Implementation Example No. 4

The first and second substrates 1, 2 are two (001) silicon wafers of 200 mm in diameter and 725 μm in thickness, covered with a thermal oxide layer of 145 nm in thickness. The first and second substrates 1, 2 are cleaned and hydrolysed in baths of ozonated deionized water and in an APM (ammonia-peroxide mixture) solution at 70° C. The first and second substrates 1, 2 are direct-bonded at ambient temperature and at ambient pressure. V₁ denotes the mean wave velocity obtained in the spontaneous propagation of the direct bond. Next, the first and second substrates 1, 2 are completely debonded. A voltage of 250 V is applied to both substrates 1, 2. The first and second substrates 1, 2 are direct-bonded anew, and a bonding wave velocity V₂ that is about twice the speed of V₁ is measured. In this example, it is not necessary to perform the first direct bonding operation, it being provided here only to show the increase in wave propagation velocity from V₁ to V₂. In this example, V₁ has a value of about 20 mm/s and V₂ has a value of about 40 mm/s.

### Implementation Example No. 5

The first and second substrates 1, 2 are two (001) silicon wafers of 200 mm in diameter and 725 μm in thickness, covered with a thermal oxide layer of 145 nm in thickness. The first and second substrates 1, 2 are cleaned and hydrolysed in baths of ozonated deionized water and in an APM (ammonia-peroxide mixture) solution at 70° C. The first and second substrates 1, 2 are direct-bonded at ambient temperature and at ambient pressure. V₁ denotes the mean wave velocity obtained in the spontaneous propagation of the direct bond. A voltage of 250 V is applied to the stack of the two bonded substrates 1, 2. The first and second substrates 1, 2 are completely debonded. The first and second substrates 1, 2 are direct-bonded anew, and a velocity V₂ that is about twice that of V₁ is measured. In this example, V₁ has a value of about 20 mm/s and V₂ has a value of about 40 mm/s.

### Implementation Example No. 6

The first and second substrates 1, 2 are two (001) silicon wafers of 200 mm in diameter and 725 μm in thickness. The first and second substrates 1, 2 are cleaned and hydrolysed in baths of ozonated deionized water and in an APM (ammonia-peroxide mixture) solution at 70° C. A dinitrogen N₂ plasma is formed on the first and second substrates 1, 2 for 15 s under a pressure of 0.3 mbar of nitrogen in RIE (reactive-ion etching) mode at a frequency of 13.56 MHz. The first and second substrates 1, 2 are direct-bonded at ambient temperature and at ambient pressure. V₁ denotes the mean wave velocity obtained in the spontaneous propagation of the direct bond. A voltage of 250 V is applied to the stack of the two bonded substrates 1, 2. The first and second substrates 1, 2 are partially debonded. The first and second substrates 1, 2 are direct-bonded anew. The direct bonding/partial debonding steps are reiterated multiple times, with the voltage being applied each time the substrates are direct-bonded. As shown in FIG. 4, the wave velocity V₂ progressively increases until reaching twice V₁. In this example, V₁ has a value of about 30 mm/s and V₂ has a value of about 60 mm/s.

The invention is not limited to the described embodiments. A person skilled in the art is capable of considering technically feasible combinations thereof and of substituting them with equivalents.

1: A process for attaching a first substrate to a second substrate by direct bonding, the first and second substrates comprising first and second surfaces, respectively, possessing an initial bonding energy;
the process including at least one step consisting in generating electrostatic charges on the first and second surfaces so as to obtain a bonding energy that is strictly higher than the initial bonding energy;
the process including the successive steps of:
providing the first and second substrates comprising the first and second surfaces, respectively, possessing the initial bonding energy;
attaching the first substrate to the second substrate by direct bonding with the first and second surfaces;
at least partially debonding the first and second substrates so as to generate electrostatic charges on portions of the first and second surfaces; and
rebonding the first substrate to the second substrate by direct bonding with said portions of the first and second surfaces.

2: The process according to claim 1, wherein said at least one step is carried out such that the generated electrostatic charges are distributed randomly over the first and second surfaces.

3: The process according to claim 1, wherein said at least one step is carried out such that the obtained bonding energy is between 50 mJ/m² and 150 mJ/m².

4: The process according to claim 1, including the successive steps of:
a) providing the first and second substrates comprising the first and second surfaces, respectively, possessing the initial bonding energy;
b) applying electric potentials to the first and second surfaces so as to generate electrostatic charges;
c) attaching the first substrate to the second substrate by direct bonding with the first and second surfaces; step c) being followed by the steps of:
c₁) partially debonding the first and second substrates so as to generate electrostatic charges on portions of the first and second surfaces; and
c₂) rebonding the first substrate to the second substrate by direct bonding with said portions (100, 200) of the first and second surfaces.

5: The process according to claim 4, wherein step c₁) is carried out such that the area of the debonded portions of the first and second surfaces is at least half that of the first and second surfaces, respectively.

6: The process according to claim 4, wherein steps c₁) and c₂) are reiterated on said debonded portions of the first and second surfaces.

7: The process according to claim 4, wherein steps c₁) and c₂) are reiterated on at least portions that are complementary to said debonded portions of the first and second surfaces.

8: The process according to claim 1, including the successive steps of:
a′) providing the first and second substrates comprising the first and second surfaces, respectively, possessing the initial bonding energy;
b′) attaching the first substrate to the second substrate by direct bonding with the first and second surfaces;
c′) partially debonding the first and second substrates so as to generate electrostatic charges on portions of the first and second surfaces; and
d′) rebonding the first substrate to the second substrate by direct bonding with said portions of the first and second surfaces.

9: The process according to claim 8, wherein step c′) is carried out such that the area of the debonded portions of the first and second surfaces is at least half that of the first and second surfaces, respectively.

10: The process according to claim 8, wherein steps c′) and d′) are reiterated on said debonded portions of the first and second surfaces.

11: The process according to claim 8, wherein steps c′) and d′) are reiterated on at least portions that are complementary to said debonded portions of the first and second surfaces.

12: The process according to claim 8, wherein step b′) includes a step consisting in applying a voltage between the bonded first and second substrates so as to generate electrostatic charges on the first and second surfaces, the voltage preferably being between 10 V and 250 V.

13: The process according to claim 8, wherein step d′) includes a step consisting in applying a voltage between the rebonded first and second substrates so as to generate electrostatic charges on the first and second surfaces, the voltage preferably being between 10 V and 250 V.

14: The process according to claim 1, including the successive steps of:
a″) providing the first and second substrates comprising the first and second surfaces, respectively, possessing the initial bonding energy;
b″) bonding the first substrate to the second substrate by direct bonding with the first and second surfaces;
c″) applying a voltage between the bonded first and second substrates so as to generate electrostatic charges on the first and second surfaces, the voltage preferably being between 10 V and 250 V; and
d″) completely debonding the first and second substrates;
e″) rebonding the first substrate to the second substrate by direct bonding with the first and second surfaces.

15: The process according to claim 1, wherein the first and second surfaces are made of a material selected from Si, Ge, Si—Ge, SiC, SiO₂, GeO₂, SiN, Al₂O₃, InP, AsGa, GaN.
